(19) United States
(12) Patent Application Publication
(10) Pub. No.: US 2007/0296034 A1
(43) Pub. Date: Dec. 27, 2007

(54) SILICON-ON-INSULATOR (SOI) MEMORY DEVICE

(76) Inventors: Hsin-Ming Chen, Tainan Hsien (TW); Shih-Chen Wang, Taipei City (TW); Ming-Chou Ho, Hsin-Chu City (TW); Shih-Jye Shen, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/759,949

(22) Filed: Jun. 8, 2007

Related U.S. Application Data
(60) Provisional application No. 60/805,751, filed on Jun. 26, 2006.

(51) Int. Cl. H01L 27/12

(52) U.S. Cl. 257/347

(57) ABSTRACT

A single-poly SOI memory cell includes a PMOS select transistor serially connected with a floating-gate PMOS transistor on an SOI substrate. The PMOS select transistor includes a select gate, a P⁺ source region and a P⁺ drain/source region. The floating-gate PMOS transistor includes a floating gate, a P⁺ drain region and the P⁺ drain/source region, wherein the P⁺ drain/source region is shared by the PMOS select transistor and the floating-gate PMOS transistor. A floating first N⁺ doping region is disposed within the P⁺ drain/source region. The first N⁺ doping region, which is adjacent to the floating gate, acts as a source-tie pick-up.

### CROSS REFERENCE TO RELATED APPLICATIONS

This application claims the benefit of U.S. provisional application No. 60/805751 filed Jun. 26, 2006.

### BACKGROUND OF THE INVENTION

1. Field of the Invention

The present invention relates to a silicon-on-insulator (SOI) memory device. More particularly, the present invention relates to a single-poly non-volatile memory cell that is fabricated on an SOI substrate wherein a well-pickup circuitry can be omitted.

2. Description of the Prior Art

As known in the art, a silicon-on-insulator (SOI) substrate has been widely used in various semiconductor products such as dynamic random access memory (DRAM), erasable programmable read only memory (EPROM), electrically erasable programmable read only memory (EEPROM), flash memory, power ICs or consumer ICs.

An SOI substrate is normally formed by the use of a separation by implantation oxygen (SIMOX) method to form a silicon dioxide isolation layer beneath the surface of a silicon substrate, or by the use of a smart cut process to form an SOI substrate with a single crystal layer, an isolation layer and a silicon substrate. Generally, the MOSFET formed on the SOI substrate is installed in the single crystal layer separated from the silicon substrate by the silicon dioxide isolation layer. The insulation provided by the isolation layer prevents both the occurrence of the latch up phenomenon of electrical devices as well as electrical breakdown of the MOSFET.

IC designers have encountered a problem when they try to incorporate some specific types of memory with an SOI substrate. FIG. 1 is a schematic layout diagram of a single-poly non-volatile memory cell according to U.S. Pat. No. 6,678,190. As shown in FIG. 1, the memory cell 1 comprises two serially connected PMOS transistors 12 and 14. The PMOS transistor 12 includes a select gate 4, a P⁺ drain/source doping region 8 and a P⁺ drain/source doping region 2. The PMOS transistor 14 includes a floating gate 6, a P⁺ drain/source doping region 9 and the P⁺ drain/source doping region 2. The two serially connected PMOS transistors 12 and 14 share the P⁺ drain/source doping region 2. This type of single-poly memory, which is also known as Neobit™ technology, was developed by the same assignee of this application (i.e., eMemory Technology Inc.) and is fully compatible with CMOS logic processes.

In operation, the select gate 4 of the PMOS transistor 12 is coupled to a select gate voltage V_{SG}, the P⁺ drain/source doping region 8 of the PMOS transistor 12 is coupled to a source line voltage V_{SL} by way of a source line contact 22, the P⁺ drain/source doping region 2 and the floating gate 6 are floating, and the P⁺ drain/source doping region 9 of the PMOS transistor 14 is coupled to a bit line voltage V_{BL} through a bit line contact 24. Under the program mode, electrons are selectively injected and stored in the floating gate 6. The major advantage of such memory structure is that it can be operated at low voltages and because both PMOS transistors 12 and 14 are single poly structures the memory cell 1 can be fabricated with standard logic processes.

FIG. 2 is a schematic diagram demonstrating the problem when incorporating the aforesaid memory cell 1 with an SOI substrate. The drawback is that electrons generated by ion impact ionization accumulate at the bottom of the bulk active layer, which adversely affect the active layer voltage (V_{bulk}) and make V_{bulk} continue to descend during operation. In addition, these accumulated electrons make the threshold voltages of the two transistors of the memory cell (particularly the threshold voltage of the floating gate transistor) descend, thereby affecting the performance of the memory device.

One approach to solving this problem is adding a well-pickup circuitry into the memory layout in order to canalize the accumulated electrons. However, this additional well-pickup circuitry results in more complex circuit design and also increased surface area per unit cell.

### SUMMARY OF THE INVENTION

It is one object of this invention to provide an improved single-poly non-volatile memory SOI device in order to solve the above-mentioned problems.

According to the claimed invention, a single-poly silicon-on-insulator (SOI) memory device is provided. The single-poly SOI memory device includes an SOI substrate; a PMOS select transistor on the SOI substrate, the PMOS select transistor including a select gate, a P⁺ source doping region and a P⁺ drain/source doping region, wherein the P⁺ source doping region is electrically connected to a source line; a floating-gate PMOS transistor serially connected to the PMOS select transistor on the SOI substrate, the floating-gate PMOS transistor including a floating gate, a P⁺ drain doping region and the P⁺ drain/source doping region, wherein the P⁺ drain/source doping region is shared by the PMOS select transistor and the floating-gate PMOS transistor; and a floating first N⁺ doping region situated within the P⁺ drain/source doping region, wherein the floating first N⁺ doping region is electrically connected with an N doping region underneath the floating gate.

According one aspect of this invention, a single-poly SOI memory device includes an SOI substrate; a PMOS select transistor on the SOI substrate, the PMOS select transistor including a select gate, a P⁺ source doping region and a P⁺ drain/source doping region, wherein the P⁺ source doping region is electrically connected to a source line; a floating-gate PMOS transistor serially connected to the PMOS select transistor on the SOI substrate, the floating-gate PMOS transistor including a floating gate, a P⁺ drain doping region and the P⁺ drain/source doping region, wherein the P⁺ drain/source doping region is shared by the PMOS select transistor and the floating-gate PMOS transistor. The floating gate is a reverse T-shaped structure including a bottom strip, wherein an N⁺ doping region is disposed in the SOI substrate and is in close proximity to the bottom strip, and wherein the N⁺ doping region is electrically connected with an N doping region underneath the floating gate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic layout diagram of a single-poly non-volatile memory cell according to the prior art.

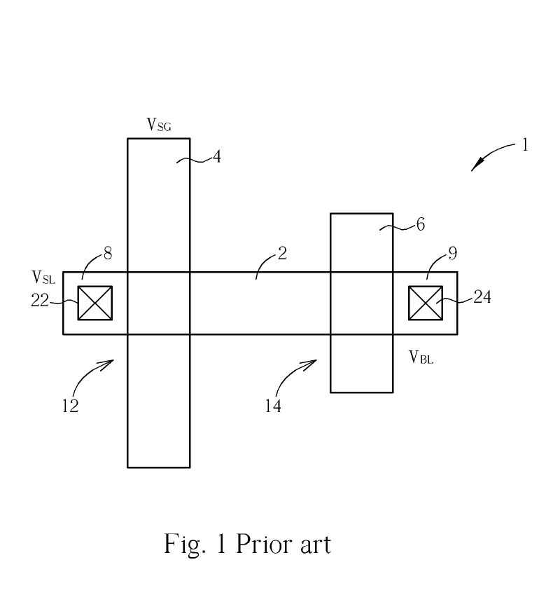

FIG. 2 is a schematic diagram demonstrating the problem when incorporating the prior art memory cell with an SOI substrate.

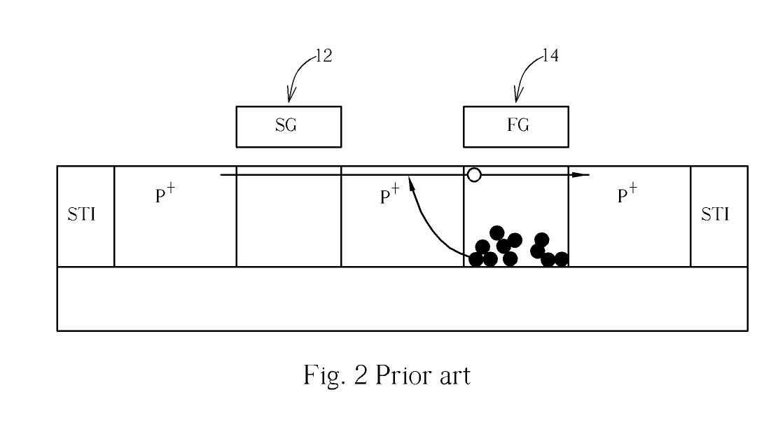

FIG. 3 is a schematic diagram showing the layout of a single-poly non-volatile memory SOI device in accordance with the first preferred embodiment of this invention.

FIG. 4 is a schematic diagram showing the layout of a single-poly non-volatile memory SOI device in accordance with the second preferred embodiment of this invention.

FIG. 5 is a schematic diagram showing the layout of a single-poly non-volatile memory SOI device in accordance with the third preferred embodiment of this invention.

FIG. 6 is a schematic diagram showing the layout of a single-poly non-volatile memory SOI device in accordance with the fourth preferred embodiment of this invention.

FIG. 7 is a schematic diagram showing the layout of a single-poly non-volatile memory SOI device in accordance with the fifth preferred embodiment of this invention.

FIG. 8 is a schematic diagram showing the layout of a single-poly non-volatile memory SOI device in accordance with the sixth preferred embodiment of this invention.

### DETAILED DESCRIPTION

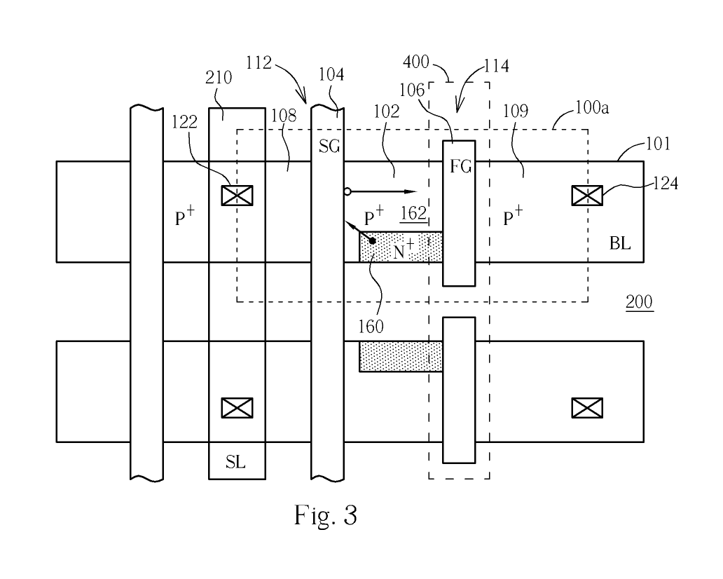

FIG. 3 is a schematic diagram showing the layout of a single-poly non-volatile memory SOI (silicon-on-insulator) device in accordance with the first preferred embodiment of this invention.

As shown in FIG. 3, the single-poly non-volatile memory SOI device comprises a cell unit 100a as the region indicated by dashed line. The cell unit 100a comprises a select gate 104, a P⁺ source doping region 108 and a P⁺ drain/source doping region 102, which constitute a select transistor 112 of the cell unit 100a. The cell unit 100a further comprises a floating gate transistor 114 serially connected with the select transistor 112. The floating gate transistor 114 comprises a floating gate 106, P⁺ drain/source doping region 102 and P⁺ drain doping region 109. The select transistor 112 and the floating gate transistor 114 share the P⁺ drain/source doping region 102. A shallow trench isolation (STI) structure 200 surrounds the active area 101.

It is to be understood that FIGS. 3-8 also illustrate a self-aligned salicided block (SAB) layer or SAB region, which is indicated by dashed line 400. A salicide layer is not formed within the SAB region. Since the SAB region is not germane to this invention, the details of this will be omitted.

The present invention single-poly non-volatile memory SOI device is fabricated on an SOI substrate. The SOI substrate comprises a silicon substrate, a buried oxide layer on the silicon substrate, and a silicon active layer on the buried oxide layer. More specifically, the present invention single-poly non-volatile memory SOI device is fabricated on the silicon active layer. The SOI substrate may be any commercially available SOI products, which can be fabricated using conventional SIMOX method, but not limited thereto. The present invention single-poly non-volatile memory SOI device may be a fully depleted SOI device or partially depleted SOI device.

In operation, the select gate 104 of the PMOS transistor 112 is coupled to a select gate voltage V_{SG}, the P⁺ source doping region 108 of the PMOS transistor 112 is connected to a source line 210 through a source line contact 122, the P⁺ drain/source doping region 102 and the floating gate 106 are floating, and the P⁺ drain doping region 109 of the PMOS transistor 114 is connected to a bit line through a bit line contact 124. Under the program mode, electrons are selectively injected and stored in the floating gate 106.

The present invention single-poly non-volatile memory SOI device is characterized in that a floating N⁺ doping region 160 is disposed within the shared P⁺ drain/source doping region 102 of the cell unit 100a. The floating N⁺ doping region 160 is in close proximity to the floating gate 106 and capacitively couples with the floating gate 106. More specifically, the floating N⁺ doping region 160 is electrically connected with an N doping region (not explicitly shown) right underneath the floating gate 106.

Due to the disposal of the floating N⁺ doping region 160 within the shared P⁺ drain/source doping region 102, holes enter the N well region right underneath the floating gate 106 from the P⁺ region 162 adjacent to the floating N⁺ doping region 160 during program or read operation, while electrons are canalized through the source line 210 by way of the floating N⁺ doping region 160. In this regard, the floating N⁺ doping region 160 functions like a source-tie well pickup, which is capable of preventing the electrons from accumulating in the SOI substrate.

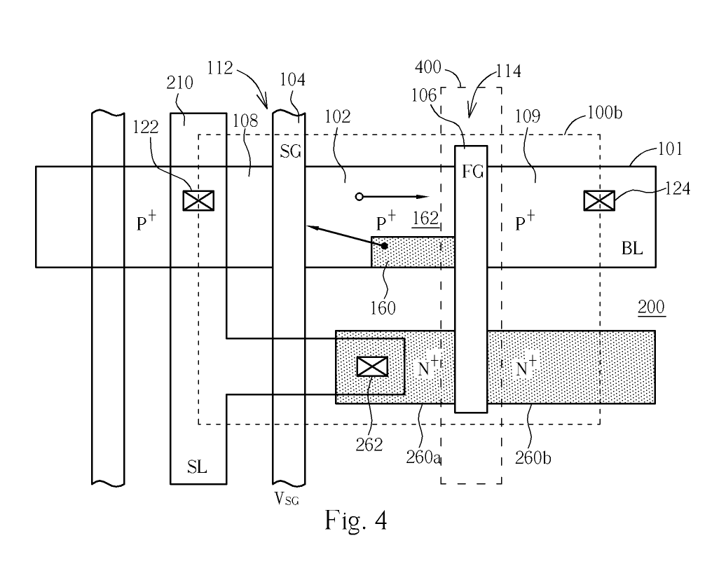

FIG. 4 is a schematic diagram showing the layout of a single-poly non-volatile memory SOI device in accordance with the second preferred embodiment of this invention, wherein like numerals designate like layers, elements or regions.

As shown in FIG. 4, the single-poly non-volatile memory SOI device comprises a cell unit 100b as the region indicated by dashed line. The cell unit 100b comprises a select gate 104, a P⁺ source doping region 108 and a P⁺ drain/source doping region 102, which constitute a select transistor 112 of the cell unit 100b. The cell unit 100b further comprises a floating gate transistor 114 serially connected with the select transistor 112. The floating gate transistor 114 comprises a floating gate 106, P⁺ drain/source doping region 102 and P⁺ drain doping region 109. The select transistor 112 and the floating gate transistor 114 share the P⁺ drain/source doping region 102. Likewise, an STI structure 200 surrounds the active area 101.

In operation, the select gate 104 of the PMOS transistor 112 is coupled to a select gate voltage V_{SG}, the P⁺ source doping region 108 of the PMOS transistor 112 is connected to a source line 210 through a source line contact 122, the P⁺ drain/source doping region 102 and the floating gate 106 are floating, and the P⁺ drain doping region 109 of the PMOS transistor 114 is connected to a bit line through a bit line contact 124. Under the program mode, electrons are selectively injected and stored in the floating gate 106.

A floating N⁺ doping region 160 is disposed within the shared P⁺ drain/source doping region 102 of the cell unit 100b. The floating N⁺ doping region 160 is in close proximity to the floating gate 106. The floating N⁺ doping region 160 is electrically connected with an N doping region (not explicitly shown) right underneath the floating gate 106.

During program or read operation, holes enter the N well region right underneath the floating gate 106 from the P⁺ region 162 adjacent to the floating N⁺ doping region 160, while electrons are canalized through the source line 210 by way of the floating N⁺ doping region 160. Analogous to the first preferred embodiment, the floating N⁺ doping region 160 functions like a source-tie well pickup for canalizing the accumulated electrons.

The difference between the cell unit 100b in FIG. 4 and the cell unit 100a in FIG. 3 is that the cell unit 100b in FIG. 4 further comprises an N⁺ doping region 260a and an N⁺ doping region 260b situated on one side of the active area 101. The floating gate 106 extends to and capacitively couples with the N⁺ doping regions 260a and 260b. The N⁺ doping region 260a is connected with the source line 210 through the contact 262. Through the N⁺ doping regions 260a and 260b, the voltage level of the source line 210 is partially coupled to the floating gate 106, thereby improving the programming ability thereof. The shortcoming is that the cell unit 100b requires relatively larger chip surface area compared to cell unit 100a because of the N⁺ doping regions 260a and 260b and the extended floating gate 106.

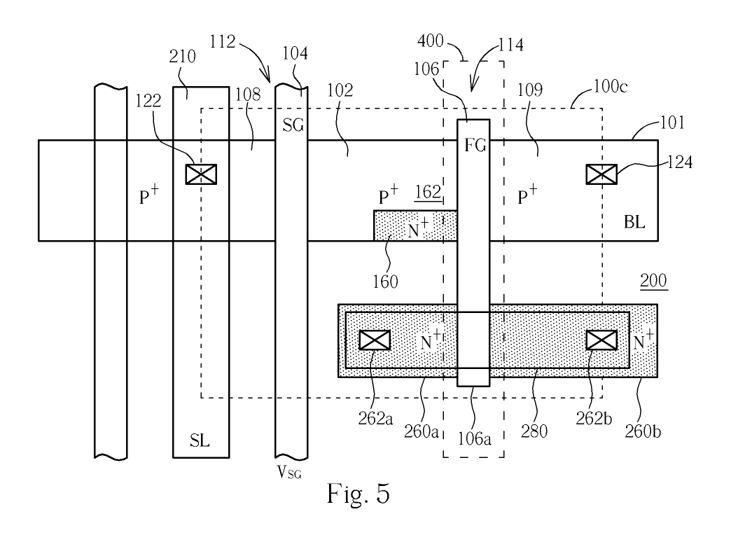

FIG. 5 is a schematic diagram showing the layout of a single-poly non-volatile memory SOI device in accordance with the third preferred embodiment of this invention.

As shown in FIG. 5, the single-poly non-volatile memory SOI device comprises a cell unit 100c as the region indicated by dashed line. The cell unit 100c comprises a select gate 104, a P⁺ source doping region 108 and a P⁺ drain/source doping region 102, which constitute a select transistor 112 of the cell unit 100c. The cell unit 100c further comprises a floating gate transistor 114 serially connected with the select transistor 112. The floating gate transistor 114 comprises a floating gate 106, P⁺ drain/source doping region 102 and P⁺ drain doping region 109. The select transistor 112 and the floating gate transistor 114 share the P⁺ drain/source doping region 102. An STI structure 200 surrounds the active area 101.

In operation, the select gate 104 of the PMOS transistor 112 is coupled to a select gate voltage V_{SG}, the P⁺ source doping region 108 of the PMOS transistor 112 is connected to a source line 210 through a source line contact 122, the P⁺ drain/source doping region 102 and the floating gate 106 are floating, and the P⁺ drain doping region 109 of the PMOS transistor 114 is connected to a bit line through a bit line contact 124. Under the program mode, electrons are selectively injected and stored in the floating gate 106.

A floating N⁺ doping region 160 is disposed within the shared P⁺ drain/source doping region 102 of the cell unit 100c. The floating N⁺ doping region 160 is in close proximity to the floating gate 106. The floating N⁺ doping region 160 is electrically connected with an N doping region (not explicitly shown) right underneath the floating gate 106 within the active area 101.

During program or read operation, holes enter the N well region from the P⁺ region 162 adjacent to the floating N⁺ doping region 160, while electrons are canalized through the source line 210 by way of the floating N⁺ doping region 160. The floating N⁺ doping region 160 acts as a source-tie well pickup for canalizing the electrons accumulated in the SOI substrate.

The cell unit 100c further comprises an N⁺ doping region 260a and an N⁺ doping region 260b both situated on one side of the active area 101. The floating gate 106 has an extended portion 106a that couples with the N⁺ doping regions 260a and 260b.

The difference between the cell unit 100c in FIG. 5 and the cell unit 100b in FIG. 4 is that the N⁺ doping region 260a of the cell unit 100c is not connected to the source line 210. Instead, a control gate 280 for coupling and adjusting voltage level overlies the N⁺ doping regions 260a and 260b. The control gate 280 is electrically connected to the underlying N⁺ doping region 260a through a contact 262a and is electrically connected to the N⁺ doping region 260b through a contact 262b. The extended portion 106a of the floating gate 106 is sandwiched between the control gate 280 and the N⁺ doping regions 260a and 260b.

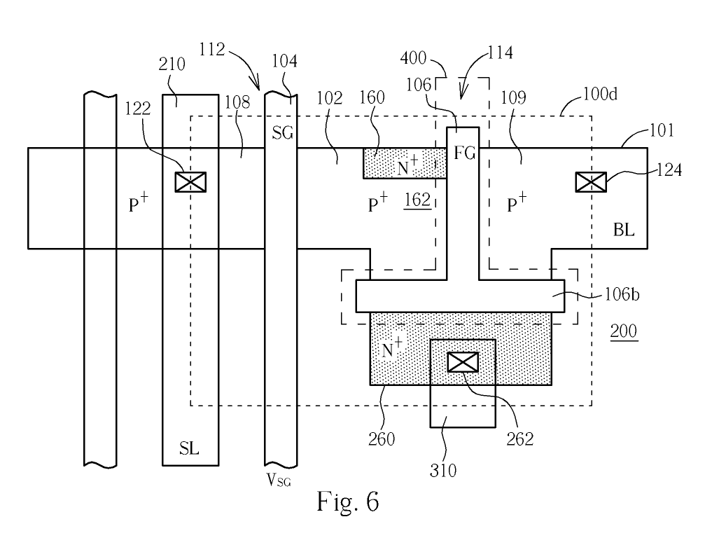

FIG. 6 is a schematic diagram showing the layout of a single-poly non-volatile memory SOI device in accordance with the fourth preferred embodiment of this invention.

As shown in FIG. 6, the single-poly non-volatile memory SOI device comprises a cell unit 100d as the region indicated by dashed line. The cell unit 100d comprises a select gate 104, a P⁺ source-doping region 108 and a P⁺ drain/source doping region 102, which constitute a select transistor 112 of the cell unit 100d. The cell unit 100d further comprises a floating gate transistor 114 serially connected with the select transistor 112. The floating gate transistor 114 comprises a floating gate 106, P⁺ drain/source doping region 102 and P⁺ drain doping region 109. The select transistor 112 and the floating gate transistor 114 share the P⁺ drain/source doping region 102. An STI structure 200 surrounds the active area 101.

In operation, the select gate 104 of the PMOS transistor 112 is coupled to a select gate voltage V_{SG}, the P⁺ source doping region 108 of the PMOS transistor 112 is connected to a source line 210 through a source line contact 122, the P⁺ drain/source doping region 102 and the floating gate 106 are floating, and the P⁺ drain doping region 109 of the PMOS transistor 114 is connected to a bit line through a bit line contact 124. Under the program mode, electrons are selectively injected and stored in the floating gate 106.

A floating N⁺ doping region 160 is disposed within the shared P⁺ drain/source doping region 102 of the cell unit 100D. The floating N⁺ doping region 160 is in close proximity to the floating gate 106. The floating N⁺ doping region 160 is electrically connected with an N doping region (not explicitly shown) right underneath the floating gate 106.

During program operation, holes enter the channel of an N well right underneath the floating gate 106 from the P⁺ region 162 adjacent to the floating N⁺ doping region 160, while electrons are canalized through the source line 210 by way of the floating N⁺ doping region 160. The floating N⁺ doping region 160 functions as a source-tie well pickup for canalizing the electrons accumulated in the SOI substrate. However, in this preferred embodiment, the floating N⁺ doping region 160 may be omitted because the cell unit 100d has another way to canalize electrons accumulated at the bulk active layer. The details will be explained as follows.

The cell unit 100d is characterized in that the floating gate 106 is a reverse T-shaped structure including an orthogonal bottom strip 106b (orthogonal to the select gate strip). An N⁺ doping region 260 is disposed in the substrate and is in close proximity to the orthogonal bottom strip 106b. The N⁺ doping region 260 is situated at one side of the orthogonal bottom strip 106b. From one aspect, the N⁺ doping region 260 protrudes from the orthogonal bottom strip 106b and capacitively couples with the floating gate 106. Preferably, the N⁺ doping region 260 is electrically connected with the N doping region right underneath the floating gate 106b.

The N⁺ doping region 260 is electrically connected to a metal line 310 through a contact 262. During program or read operation, electrons gradually accumulated at the bottom of the bulk active layer underneath the floating gate 106 can be canalized through the orthogonal bottom strip 106b, the N⁺ doping region 260, the contact 262 and the metal line 310. Therefore, the device performance can be maintained and the N⁺ doping region 160 can be omitted.

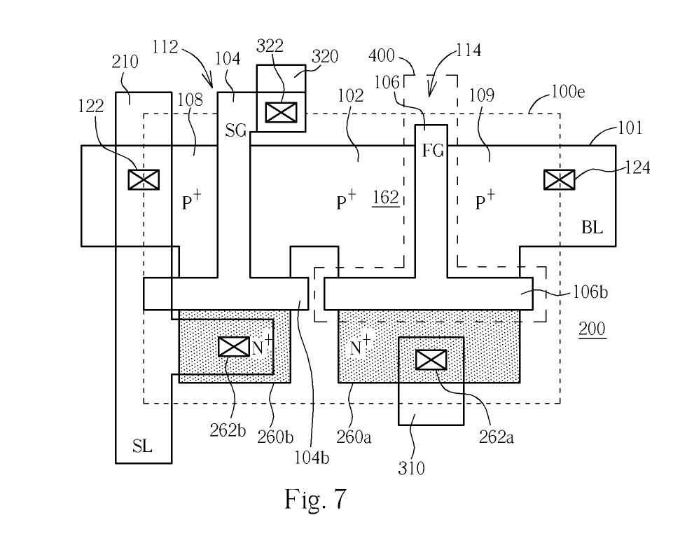

FIG. 7 is a schematic diagram showing the layout of a single-poly non-volatile memory SOI device in accordance with the fifth preferred embodiment of this invention.

As shown in FIG. 7, the single-poly non-volatile memory SOI device comprises a cell unit 100e as the region indicated by dashed line. The cell unit 100e comprises a select gate 104, a P⁺ source-doping region 108 and a P⁺ drain/source doping region 102, which constitute a select transistor 112 of the cell unit 100e. The cell unit 100e further comprises a floating gate transistor 114 serially connected with the select transistor 112. The floating gate transistor 114 comprises a floating gate 106, P⁺ drain/source doping region 102 and P⁺ drain doping region 109. The select transistor 112 and the floating gate transistor 114 share the P⁺ drain/source doping region 102. An STI structure 200 surrounds the active area 101.

In operation, the select gate 104 of the PMOS transistor 112 is coupled to a select gate voltage V_{SG}, the P⁺ source doping region 108 of the PMOS transistor 112 is connected to a source line 210 through a source line contact 122, the P⁺ drain/source doping region 102 and the floating gate 106 are floating, and the P⁺ drain doping region 109 of the PMOS transistor 114 is connected to a bit line through a bit line contact 124. Under the program mode, electrons are selectively injected and stored in the floating gate 106.

The floating gate 106 is a reverse T-shaped structure including an orthogonal bottom strip 106b. An N⁺ doping region 260a is disposed in the substrate and is in close proximity to the orthogonal bottom strip 106b. The N⁺ doping region 260a is situated at one side of the orthogonal bottom strip 106b and is electrically connected to an N doping region underneath the floating gate 106b. The N⁺ doping region 260a is electrically connected to a metal line 310 through a contact 262a.

The difference between the cell unit 100e in FIG. 7 and the cell unit 100d in FIG. 6 is that the select gate 104 of the cell unit 100e is also a reverse T-shaped structure, wherein the select gate 104 of the cell unit 100e includes an orthogonal bottom strip 104b. An N⁺ doping region 260b is disposed in the substrate and is in close proximity to the orthogonal bottom strip 104b. The N⁺ doping region 260b is situated at one side of the orthogonal bottom strip 104b and is electrically connected to an N doping region underneath the select gate 104. The N⁺ doping region 260b is electrically connected to the source line 210 through a contact 262b. In this preferred embodiment, the select gate 104 is interconnected through a contact 322 and a metal line 320.

According to the fifth preferred embodiment of this invention, during program or read operation, the electrons gradually accumulated at the bottom of the bulk active layer underneath the select gate 104 can be canalized through the orthogonal bottom strip 104b, the N⁺ doping region 260b, the contact 262b and the source line 210. It is understood that the connection between the N⁺ doping region 260b and the source line 210 is not necessary. The N⁺ doping region 260b may be coupled with an independent electrode that is capable of controlling or adjusting voltage level.

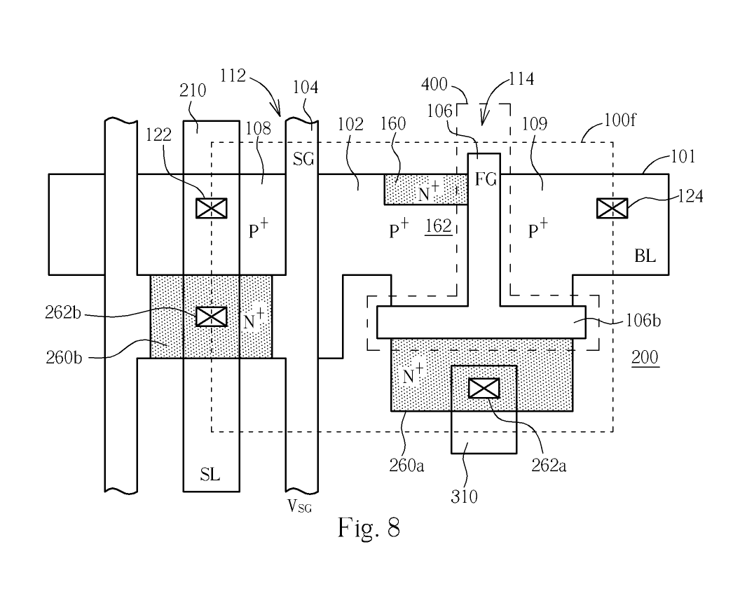

FIG. 8 is a schematic diagram showing the layout of a single-poly non-volatile memory SOI device in accordance with the sixth preferred embodiment of this invention.

As shown in FIG. 8, the single-poly non-volatile memory SOI device comprises a cell unit 100f as the region indicated by dashed line. The cell unit 100f comprises a select gate 104, a P⁺ source-doping region 108 and a P⁺ drain/source doping region 102, which constitute a select transistor 112 of the cell unit 100f. The cell unit 100f further comprises a floating gate transistor 114 serially connected with the select transistor 112. The floating gate transistor 114 comprises a floating gate 106, P⁺ drain/source doping region 102 and P⁺ drain doping region 109. The select transistor 112 and the floating gate transistor 114 share the P⁺ drain/source doping region 102. An STI structure 200 surrounds the active area 101.

In operation, the select gate 104 of the PMOS transistor 112 is coupled to a select gate voltage V_{SG}, the P⁺ source doping region 108 of the PMOS transistor 112 is connected to a source line 210 through a source line contact 122, the P⁺ drain/source doping region 102 and the floating gate 106 are floating, and the P⁺ drain doping region 109 of the PMOS transistor 114 is connected to a bit line through a bit line contact 124. Under the program mode, electrons are selectively injected and stored in the floating gate 106.

Similar to the cell unit 100e in FIG. 7, the floating gate 106 of the cell unit 100f of FIG. 8 is a reverse T-shaped structure including an orthogonal bottom strip 106b. An N⁺ doping region 260a is disposed in the substrate and is in close proximity to the orthogonal bottom strip 106b. The N⁺ doping region 260a is situated at one side of the orthogonal bottom strip 106b and is electrically connected to an N doping region underneath the floating gate 106b. The N⁺ doping region 260a is electrically connected to a metal line 310 through a contact 262a.

The difference between the cell unit 100f in FIG. 8 and the cell unit 100e in FIG. 7 is that the select gate 104 of the cell unit 100f is not reverse T-shaped, but substantially line-shaped. At one side of the line-shaped select gate 104 of the cell unit 100f, an N⁺ doping region 260b is disposed in the substrate. The N⁺ doping region 260b is in close proximity to one side of the select gate 104 and is electrically connected to an N doping region underneath the select gate 104. Besides, the N⁺ doping region 260b borders the P⁺ source-doping region 108. The N⁺ doping region 260b is electrically connected to the source line 210 through the contact 262b, while the N⁺ doping region 260b is electrically connected to the source line 210 through the contact 262b.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A single-poly silicon-on-insulator (SOI) memory device, comprising:
an SOI substrate;
a PMOS select transistor on said SOI substrate, said PMOS select transistor including a select gate, a P⁺ source doping region and a P⁺ drain/source doping region, wherein said P⁺ source doping region is electrically connected to a source line;
a floating-gate PMOS transistor serially connected to said PMOS select transistor on said SOI substrate, said floating-gate PMOS transistor including a floating gate, a P⁺ drain doping region and said P⁺ drain/source doping region, wherein said P⁺ drain/source doping region is shared by said PMOS select transistor and said floating-gate PMOS transistor; and
a floating first N⁺ doping region situated within said P⁺ drain/source doping region, wherein said floating first N⁺ doping region is connected to an N doping region right underneath said floating gate and is capacitively coupling with said floating gate.

2. The single-poly SOI memory device according to claim 1 wherein, during program or read operation, holes enter said N doping region from said P⁺ drain/source doping region adjacent to said floating first N⁺ doping region, while electrons are canalized through said source line by way of said floating first N⁺ doping region, wherein said floating first N⁺ doping region functions as a source-tie well pickup for preventing said electrons from accumulating in said SOI substrate.

3. The single-poly SOI memory device according to claim 1 wherein in operation, said select gate of said PMOS select transistor is coupled to a select gate voltage V_{SG}, said P⁺ drain/source doping region and said floating gate are floating, and said P⁺ drain doping region is electrically connected to a bit line.

4. The single-poly SOI memory device according to claim 1 wherein said single-poly SOI memory device is a fully depleted SOI device.

5. The single-poly SOI memory device according to claim 1 wherein said single-poly SOI memory device is a partially depleted SOI device.

6. The single-poly SOI memory device according to claim 1 wherein said floating gate comprises an extended portion that extends to an active area across a shallow trench isolation (STI) region and capacitively couples with a second N⁺ doping region and a third N⁺ doping region formed in said active area.

7. The single-poly SOI memory device according to claim 6 wherein said second N⁺ doping region and said third N⁺ doping region are disposed at two opposite sides of said extended portion.

8. The single-poly SOI memory device according to claim 6 wherein said second N⁺ doping region is electrically connected to said source line.

9. The single-poly SOI memory device according to claim 6 wherein said second N⁺ doping region and said third N⁺ doping region are connected to a control gate capable of controlling or adjusting voltage levels.

10. A single-poly silicon-on-insulator (SOI) memory device, comprising:
an SOI substrate;
a PMOS select transistor on said SOI substrate, said PMOS select transistor including a select gate, a P⁺ source doping region and a P⁺ drain/source doping region, wherein said P⁺ source doping region is electrically connected to a source line;
a floating-gate PMOS transistor serially connected to said PMOS select transistor on said SOI substrate, said floating-gate PMOS transistor including a reverse T-shaped like floating gate, a P⁺ drain doping region and said P⁺ drain/source doping region, wherein said P⁺ drain/source doping region is shared by said PMOS select transistor and said floating-gate PMOS transistor; and
an N⁺ doping region disposed in said SOI substrate and connected to an N doping region directly underneath said reverse T-shaped like floating gate, wherein said N⁺ doping region protrudes from a bottom strip of said reverse T-shaped like floating gate and capacitively couples with said reverse T-shaped like floating gate.

11. The single-poly SOI memory device according to claim 10 wherein said N⁺ doping region is electrically connected to an electrode capable of controlling or adjusting voltage levels.
